(19) United States
(12) Patent Application Publication
(10) Pub. No.: US 2008/0185729 A1
(43) Pub. Date: Aug. 7, 2008

(54) SEMICONDUCTOR ELEMENT UNIT AND COMPLEX THEREOF, SEMICONDUCTOR DEVICE AND MODULE THEREOF, ASSEMBLED STRUCTURE THEREOF AND FILM SUBSTRATE CONNECTION STRUCTURE

(75) Inventors: Masahiro Yamaguchi, Tokyo (JP); Naoya Kanda, Tokyo (JP); Yasuo Amano, Tokyo (JP); Shigeharu Tsunoda, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 12/022,516

(22) Filed: Jan. 30, 2008

(30) Foreign Application Priority Data
Jan. 31, 2007 (JP) 2007-022400

(51) Int. Cl. H01L 23/48

(52) U.S. Cl. 257/774; 257/E23.01

(57) ABSTRACT

A semiconductor device is provided with a film substrate that has through-vias that are formed by filling a conductive material in through-holes that pass through the front and rear of a film-shaped substrate body and wiring or terminals that connect to the through-vias, with a semiconductor element being mounted on the film-shaped substrate body by terminal members thereof being electrically connected to the wiring or terminals of the film substrate.

### BACKGROUND OF THE INVENTION

1. Field of the Invention

The present invention relates to a semiconductor device. More specifically, the present invention relates to a semiconductor element unit with a multistage, stacked structure with a high connection reliability that constitutes a mounting system with low parasitic inductance and capable of high-speed signal transmission, which are necessary for a high-speed memory implementation, a complex thereof, a semiconductor device, a module thereof, an assembled structure thereof and a film substrate connection structure.

Priority is claimed on Japanese Patent Application No. 2007-22400, filed Jan. 31, 2007, the content of which is incorporated herein by reference.

2. Description of Related Art

In the case of mounting a semiconductor element on a substrate, Japanese Patent No. 3809125 discloses a conventional structure of electrical joining by melting and solidifying a solder layer that is provided on a mounting substrate via projection electrodes that are provided on the semiconductor element.

However, in memory or large-scale logic chips of a large chip size with a high speed and large capacity, since there is large difference in the thermal expansion coefficients of the semiconductor element and the mounting substrate, there are cases of the solder joints being damaged until the solder solidifies from the melted state, becoming one cause that brings about a drop in the mounting yield.

As a countermeasure, a method has been developed of distributing the force that concentrates on solder joints by putting a thermosetting resin between the semiconductor element and the mounting substrate and hardening the resin simultaneously with the solder bonding.

Also, in the case of stacking a plurality of semiconductor elements in the middle of one semiconductor device, a stacked semiconductor device is manufactured by a method such as wire bonding the semiconductor element to the mounting substrate, moreover stacking the semiconductor element thereon, and wire bonding.

This issue has conventionally been resolved by mounting a semiconductor element on a multilayer substrate that has a microstrip structure and a low resistance power supply layer to constitute a semiconductor device.

However, in the prior art, in the case of stacking semiconductor devices, since it was essential to form connections via solder, stacked assembly could not be realized under the solder melting temperature. Also, as far as making connections at a high temperature using molten solder, due to the large difference in the thermal expansion coefficients of the semiconductor element and the mounting substrate, the solder joints are susceptible to breakage, and it has not been possible to improve the mounting yield.

### SUMMARY OF THE INVENTION

The present invention was achieved in view of the above circumstances, and has as its object to provide a semiconductor element unit that lowers resistance of the power supply and hinders unnecessary electromagnetic radiation from outside, has low parasitic inductance and allows assembly at low temperatures, as well as a complex thereof, and a semiconductor device, and a module thereof, and assembled structure thereof and a film substrate connection structure.

Also, another object of the present invention is to provide a structure that enables stacking of semiconductor devices at a temperature lower than the solder melting temperature.
(1) A semiconductor element unit of the present invention includes a film substrate provided with through-vias having a conductive metal material filled in through-holes that pass through the front and rear of a film-shaped substrate body, and wiring or terminals that connect to the through-vias. The semiconductor element unit further includes a semiconductor element provided with terminal members and attached to the film-shaped substrate body with the terminal members electrically connected to the wiring or the terminals.
(2) In semiconductor element unit of the present invention, it is preferable that the wiring or the terminals of the film-shaped substrate body and the terminal members of the semiconductor element are bonded.
(3) In the semiconductor element unit of the present invention, it is preferable that at least the front face of the terminal members formed on the semiconductor element and at least the front face of the wiring or the terminals of the film-shaped substrate body include a covering layer that has Au as a main component.
(4) A semiconductor device of the present invention includes the film-shaped substrate body of the semiconductor element unit recited in (1), the film-shaped substrate body of the semiconductor element unit being bonded to a multilayer wiring substrate, with the through-vias ultrasonically bonded to wiring or terminals on the front face side of the multilayer wiring substrate.
(5) A semiconductor device of the present invention includes the film-shaped substrate body of the semiconductor element unit recited in (1), the film-shaped substrate body of the semiconductor element unit being bonded to a multilayer wiring substrate, with the through-vias ultrasonically bonded to wiring or terminals on vias on the front face side of the multilayer wiring substrate.
(6) A semiconductor element unit complex of the present invention includes a plurality of the semiconductor element units recited in (1) which are stacked. A film-shaped substrate body of an upper-stage side semiconductor element unit is disposed on a semiconductor element of a lower-stage side semiconductor element unit. The substrate body is flexed toward the lower-stage side semiconductor element unit. The end portions of the film-shaped substrate body of the upper-stage side semiconductor element unit and the end portions of the film-shaped substrate body of the lower-stage side semiconductor element unit are aligned in the surface direction of the multilayer wiring substrate and ultrasonically bonded to wiring or terminals on the side of the multilayer wiring substrate.
   (7) A semiconductor element unit complex of the present invention includes a plurality of the semiconductor element units recited in (1) being stacked. Together with a plurality of the semiconductor element units, a film-shaped substrate body of an upper-stage side semiconductor element unit is disposed on a semiconductor element of a lower-stage side semiconductor element unit. The substrate body is flexed toward the lower-stage side semiconductor element unit. The end portion side of the substrate body is aligned on the substrate body of the lower-stage side semiconductor element unit, and through-vias of the upper-stage side substrate body are ultrasonically bonded to wiring or terminals on the multilayer wiring substrate via through-vias of the lower-stage side substrate body to bond the upper and lower semiconductor element units.
(8) A semiconductor device of the present invention has a structure in which, among a plurality of the semiconductor element unit complexes recited in (6) or (7), the film-shaped substrate bodies of the semiconductor element units are bonded to the multilayer wiring substrate by ultrasonically bonding the through-vias to the wiring or terminals on the front face side of the multilayer wiring substrate.
(9) A semiconductor device of the present invention has a structure in which, among a plurality of the semiconductor element unit complexes recited in (6) or (7), the film-shaped substrate bodies of the semiconductor element units are bonded to the multilayer wiring substrate by ultrasonically bonding the through-vias to the wiring or terminals on vias of the front face side of the multilayer wiring substrate.
(10) A semiconductor element unit complex of the present invention has a structure in which spacer substrates that have a thickness equal to or greater than the semiconductor element are disposed on the film-shaped substrate body of the semiconductor element unit recited in (1) so as to be positioned around the semiconductor element, through-vias that are formed by filling a conductive metal material in through-holes that are provided passing through the front and rear of the spacer substrates, the through-vias that are formed in the spacer substrates are installed on the through-vias that are provided in the film-shaped substrate body, and the spacer substrates are bonded to the substrate body by ultrasonically bonding both vias.
(11) A semiconductor device module of the present invention has a structure in which a plurality of the semiconductor element unit complexes recited in (10) are vertically stacked, and through-vias of an upper-stage side semiconductor element unit complex are installed on through vias of a lower-stage side semiconductor element unit complex, and the lower-stage side semiconductor element unit complex and the upper-stage side semiconductor element unit complex are bonded by ultrasonically bonding the vias thereof.
(12) The semiconductor device module of the present invention has a structure in which in the plurality of semiconductor element unit complexes of (10) that are stacked, through-vias that bond the film-shaped substrate bodies of the upper and lower semiconductor element unit complexes are connected in a vertical line from the through-vias of the uppermost-stage semiconductor element unit complex to the through-vias of the lowermost-stage semiconductor element unit complex.
(13) A semiconductor device module assembled structure of the present invention includes the semiconductor device module recited in (11) or (12) bonded to a multilayer wiring substrate by ultrasonically bonding the through-vias of the lowermost-stage film-shaped substrate body through-vias to electrodes on the side of the multilayer wiring substrate.
(14) The semiconductor device module assembled structure of the present invention has a structure in which wiring or terminals electrically connected by the through-vias are provided on the front face side and rear face side of the film-shaped substrate bodies, and the plurality of terminal members of the semiconductor elements of the plurality of semiconductor device modules that are vertically stacked are connected to the wiring or terminals of the multilayer wiring substrate via the wiring or terminals and through-vias of the film-shaped substrate bodies.
(15) A film substrate connection structure of the present invention has a structure in which through-holes that pass through a substrate body in the thickness direction are formed in a film substrate that is provided with the film-shaped substrate body, through-vias that are formed by filling a conductive material in the through-holes; a bonding layer that consists of a plurality of covering layers of a conductive material is formed on at least one of the bonding faces of the through-vias positioned on the front face side or the rear face side of the substrate body; wiring or terminals are formed on the mounting substrate that includes a rigid substrate to which the film substrate is bonded; and the film substrate is bonded to the mounting substrate by ultrasonically bonding the front-most face covering bonding layer of the through-vias to the front face layer of the wiring or terminals of the mounting substrate.
(16) The film substrate connection structure of the present invention has a structure in which the front-most face of the bonding layer recited in (15) includes a covering bonding layer that has Au as a main component, and the front-most face layer of the wiring includes a front face layer that has Au as a main component, and the film substrate causes the covering bonding layer that has Au as the main component to abut the front face layer that has Au as the main component so that the through-vias are ultrasonically bonded.
(17) A film substrate connection structure of the present invention has a structure in which through-holes passing through a substrate body in the thickness direction are formed in a film substrate that is provided with the film-shaped substrate body; through-vias are formed by filling a conductive material in the through-holes; and a bonding layer is formed on at least one of the bonding faces of the through-vias positioned on the front face side or the rear face side of the substrate body, and along with the film substrate being constituted, the plurality of film substrates are stacked with the through-vias that are provided in each film substrate being stacked in the vertical direction at the same position in the surface direction of the film substrates, and the stacked film substrates are bonded by bonding the through-vias that are vertically stacked with ultrasonic bonding.
(18) The film substrate connection structure of the present invention has a structure in which the front-most face layer of the bonding layer of the through-vias includes a covering bonding layer that has Au as a main component, and the film substrates are bonded via the stacked through-vias by the covering bonding layer having Au as the main component being ultrasonically bonded to the covering bonding layer of another film substrate.

According to the present invention, by using film wiring substrates that allow circuit formation on the front and rear, wiring suitable for high speed signal transmission (for example, microstrip configuration) is formed, and by ultrasonically bonding projection terminals formed on the semiconductor element, electrical connections with low parasitic inductance are achieved.

Moreover, by having through-vias that electrically connect the front and rear of the film substrate, and by essentially filling those through-vias with a metal by a method such as plating or the like, ultrasonic vibration is easily transmitted. Because of this structure, it is possible to achieve ultrasonic bonding between the multilayer substrate which is the next mounting state at a temperature that is close to room temperature, which is lower than the solder melting temperature. By utilizing this ultrasonic joining means via through-vias, it is possible to comparatively easily constitute even film substrate multi-stage stacked structures comparatively easily without concern to temperature hierarchy.

In the case of performing ultrasonic bonding, bonding via Au and Au of portions to be bonded have the most reliable and favorable bonding.

Accordingly, in the case of bonding a film substrate to a multilayer substrate with high rigidity such as a rigid substrate or the like and not a film substrate, if the film substrate side has through-vias, ultrasonic bonding is possible via the through-vias that are provided in the film-shaped substrate body even if the multilayer substrate side is any of wiring, terminals, or vias.

In the case of a constitution that stacks a plurality of semiconductor element units which are bonded to a mounting substrate, it is possible to obtain a semiconductor element unit complex that uses only conforming articles of semiconductor element units. The conforming articles of semiconductor element units can be selected, for instance, by performing a high frequency driving test, that is, a high speed test close to the actual use state for each unit of the semiconductor element unit.

Also, if adopting a structure that stacks only the required number after making a semiconductor element unit complex with a flat top face with the semiconductor element surrounded by spacer substrates, it is possible to readily stack through-vias of the film substrates of semiconductor element unit complexes that are vertically stacked. This makes it possible to realize ultrasonic bonding of a plurality of semiconductor element unit complexes via the stacked through-vias, and possible to obtain a semiconductor device module of a structure in which a plurality of the semiconductor element unit complexes are bonded and integrated.

Since this semiconductor device module is integrated by bonding of through-vias that are vertically stacked, the bondability of the semiconductor element unit complexes is good. Even when the low rigidity of flexibility such as a film substrate is stacked, the handling as a whole exhibits rigidity of a sufficient extent, and is excellent in handling.

### BRIEF DESCRIPTION OF THE DRAWINGS

FIG. 1 is a conceptual drawing showing a structure that shows one example of a semiconductor element unit that is provided with a semiconductor element and film substrate according to the present invention and a semiconductor device that provides the semiconductor element unit on a mounting substrate.

FIG. 2 is a conceptual drawing that shows the state of ultrasonic bonding in the same semiconductor device and shows an aggregate substrate that that attaches the same semiconductor device.

FIG. 3 is an enlarged sectional view of the through-via of the film substrate in the structure of the same semiconductor device.

FIG. 4 is a conceptual view that shows an embodiment according to the semiconductor element unit complex of the present invention.

FIG. 5 is a conceptual view that shows the state of bonding the same semiconductor element unit complex to the mounting substrate.

FIG. 6 is a conceptual view that shows another embodiment according to the semiconductor element unit complex of the present invention.

FIG. 7 is a conceptual view that shows the semiconductor device module that has the same semiconductor element unit complex as a stacked structure.

FIG. 8 is a conceptual view that shows the assembled structure of the semiconductor device module that bonds the same semiconductor device module to the mounting substrate.

FIG. 9 is a conceptual view that shows another example of the assembled structure of the semiconductor device module that bonds the same semiconductor device module to the mounting substrate.

FIG. 10 is a conceptual view that shows a second embodiment according to the semiconductor element unit complex of the present invention.

FIG. 11 is a conceptual view that shows a third embodiment according to the semiconductor element unit complex of the present invention.

### DETAILED DESCRIPTION OF THE INVENTION

The semiconductor element unit or semiconductor device and the like according to one embodiment of the present invention shall be described with reference to the drawings, however, the present invention is not limited to the embodiment described hereinbelow.

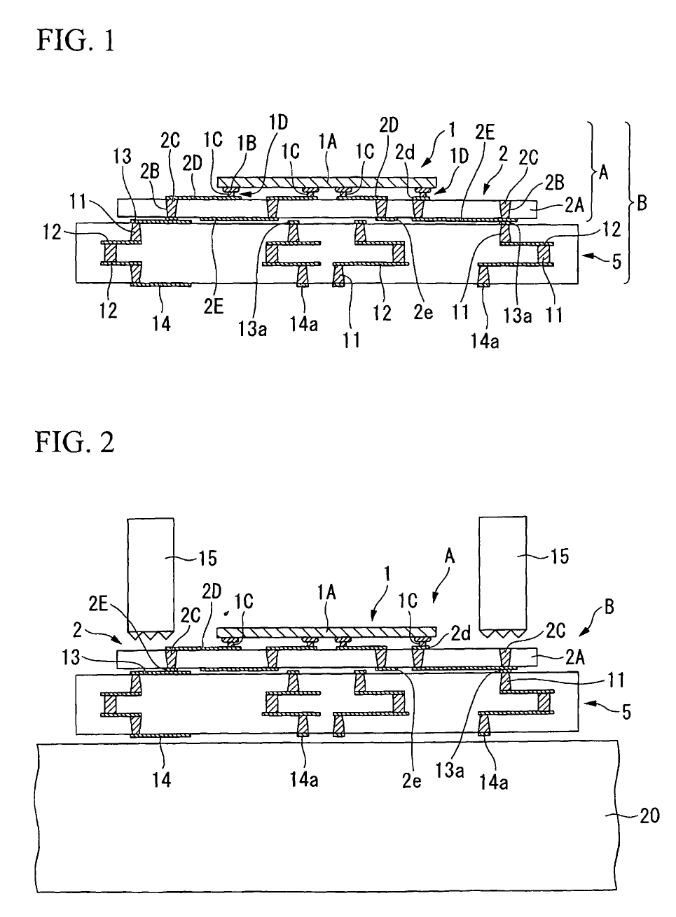

FIG. 1 is a conceptual diagram showing a sectional structure of the first embodiment of a semiconductor device B that is equipped with the semiconductor element unit A according to the present invention.

In FIG. 1, the semiconductor element unit A is constituted by a semiconductor element 1 being mounted on a film substrate 2, and the semiconductor device B is constituted by this semiconductor element unit A being mounted on a mounting substrate 5.

The semiconductor element 1 is a package component that is provided with a plate-shaped sealed body 1A that includes within functional elements consisting of circuits represented by various kinds of ICs (integrated circuits), LSI (large scale integration) and the like, or an MPU (Micro Processing Unit), an MCU (Micro Controller Unit), a DRAM (Dynamic Random Access Memory), an SRAM (Static Random Access Memory), or a gate array and the like mounted individually or compositely in the inner portion, with those functional devices sealed with a sealing material such as resin or ceramic. The semiconductor element 1 has a basic shape of a plurality of terminal members 1D being formed on the bottom side of the sealed body 1A, with each terminal member 1D consisting of a convex-shaped terminal base portion 1B and a projection terminal 1C that is formed in a projecting shape from the terminal base portion 1B. Note that a structure in which a plurality of the terminal members 1D are provided on the bottom side of the sealed body 1A is shown as an example of the semiconductor element 1 in the present embodiment. However, package-type semiconductor elements come in other various shapes, such as a structure of a plurality of leg-shaped terminals being provided from the side surface of the plate-shaped sealed body 1A, a shape of a plurality of needle-shaped or pin-shaped terminals being provided on the bottom surface of the sealed body 1A, a structure of providing solder balls that have a terminal action, and the like. The present invention can be widely applied to a semiconductor element of any shape, provided it has a constitution in which terminal members are provided projecting from the sealed body 1A.

Also, the semiconductor device B that is provided with the semiconductor element 1 and the film base substrate 2 of the present embodiment may be an internal substrate (interposer) that is enclosed within a semiconductor package. The mounting substrate 5 can also be regarded as a memory module, a module substrate of a so-called SiP (System in Package) or SoP (Small Outline Package), or package substrate.

The projection terminal 1C of the terminal member 1D is a pin type that consists of a metal conductor with a round shape (R shape). At the distal end portion of this projection terminal 1C, it is preferable that an Au-plated layer be formed having Au as a main body via an Ni foundation layer. A layer having Au (gold) as a main body in the present invention means Au with a concentration of at least 50% and for example it is possible to apply a layer of any concentration such as a deposition plated type Au plate layer with a high purity of 99% or greater, a 24K plate layer of 98% purity, a 14K Au alloy plate layer with a purity of approximately 56% to 60% provided it is a layer with Au as the main body.

The film substrate 2 is constituted by being equipped with a substrate body 2A that consists of a thermoplastic resin film having flexure (such as (PI) polyimide film etc.), a through-via 2C at each of a plurality of through-holes 2B that pass through the substrate body 2A in the thickness direction that are filled with a conductive metal material such as plated copper, a wiring 2D or terminal 2d on the top face side that are formed on the top face side of the substrate body 2A and connected to the through-via 2C, and wiring 2E on the rear face side that is formed on the rear face side of the substrate body 2A and connected to the through-via 2C.

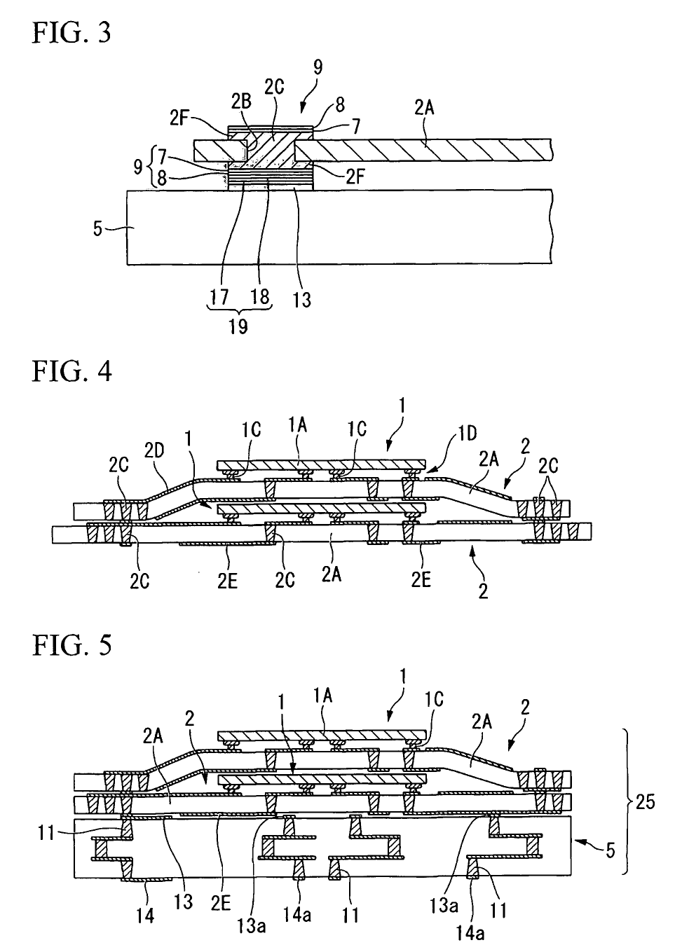

The through-via 2C is formed so as to fill the through-hole 2B with a conductive metal material such as plated copper as shown up close in FIG. 3, and is formed in a rivet shape so as to have a flange portion 2F of a larger diameter than the through-hole 2B on the top face side and the rear face side of the substrate body 2A. Also, in the through-via 2C, a bonding layer 9 that consists of a foundation layer 7 of Ni plate and a covering layer 8 having Au as the main component is formed on the top face side of the flange portion 2F that is provided on the front face side of the substrate body 2A, and a bonding layer 9 that consists of a foundation layer 7 of Ni plate and a covering layer 8 having Au as the main component is formed on the bottom face side of the flange portion 2F that is provided on the rear face side of the substrate body 2A. Also, the foundation layer 7 and the covering layer 8 having Au as its main component are preferably covered on a wiring 13 or terminal 13a described below that is formed by being exposed on the top face or rear face side of the film base plate 2.

Note that the through-via 2C has in this embodiment a structure of being formed in a rivet shape and retained. However, the shape of the through-via 2C is not limited to a rivet shape, with a shape of being continuous with the wiring or terminal, or a column shape that is simply filled in the through-hole 2B also acceptable.

The mounting substrate 5 has a structure that is known as a multilayer wiring printed circuit board, and so is configured by bonding and integrating internal printed circuit boards of a plurality of layers. Field-vias 11 of a type that pass through the internal printed circuit boards at each layer and internal wiring 12 that is provided on the top face portion side and rear face portion side of the internal printed circuit boards are provided. On the top face side of the mounting substrate 5, among the field-vias 11 that pass through the internal printed circuit boards, front face side wiring 13 and top face side terminals 13a that are connected to those field-vias 11 that reach the top face of the mounting substrate 5 are provided. On the rear face side of the mounting substrate 5, among the field-vias 11 that pass through the internal printed circuit boards, rear face side wiring 14 and rear face side terminals 14a that are connected to those field-vias 11 that reach the rear face of the mounting substrate 5 are provided. Also, a bonding layer 19 that consists of a foundation layer 17 of Ni plate and a covering layer 18 having Au as the main component is formed on the front face side wiring 13 and top face side terminals 13a of the mounting substrate 5.

This mounting substrate 5 has a rigid structure, and is made to have a higher rigidity than the film-shaped substrate body 2A by mixing a filler or the like in a thermoplastic resin and hardening.

The projection terminals 1C of the semiconductor element 1 are electrically connected by a bonding material such as solder at a portion that is connected to the wiring 2D of the film substrate 2. However, those connected to the through-via 2C at the projection terminal 1C are ultrasonically bonded.

To join the semiconductor element 1 to the film substrate 2 using an ultrasonic bonding tool 15 as shown in FIG. 2, it is possible to perform ultrasonic bonding by, after stacking the semiconductor element 1 and the film substrate 2, pushing the semiconductor element 1 from the top and imposing the ultrasonic bonding tool 15 from the rear face side, or stacking the semiconductor element 1 and the film substrate 2 upside down to the state shown in FIG. 1 and pressing and abutting the ultrasonic bonding tool 15 from above.

It is possible to reliably perform ultrasonic bonding under the conditions of a bonding frequency of 50 kHz, a bonding temperature of 25 degrees C., a bonding load of 5 to 10 N, amplitude of 8 to 16 μm, bonding time of 0.2 seconds, polyimide film substrate thickness of 50 μm, and copper though-via diameter of 30 μm.

Also, ultrasonic bonding is performed for the portion of the through-via 2C of the film substrate 2 to be bonded to the mounting substrate 5. For the portions that position the through-via 2C of the film substrate 2 on the field-vias 11 positioned on the front face portion of the mounting substrate 5, by pressing the ultrasonic bonding tool 15 from above, it is possible to perform ultrasonic bonding under the conditions given above. Also, for the portions that position the through-via 2C of the film substrate 2 on the front face side wiring 13 positioned on the front face portion of the mounting substrate 5, by pressing the ultrasonic bonding tool 15 from above, it is possible to perform ultrasonic bonding under the conditions given above.

In order to perform ultrasonic bonding with the ultrasonic bonding tool 15, it is necessary to accurately transmit ultrasonic waves to a bonding region while applying the necessary pressure with the ultrasonic bonding tool 15. Here, when interposing something that causes vibration attenuation such as resin or a flexible material between the ultrasonic bonding tool 15 and the bonding region, ultrasonic bonding becomes extremely difficult. For example, when ultrasonic bonding is attempted with a bonding tool on two film substrates in which wiring is formed on polyamide film substrate bodies by abutting the wiring together and adding pressure so as to sandwich them, the thermoplastic resin such as polyamide that is held between the wiring attenuates the ultrasonic vibration and changes the vibration frequency that is transmitted to the sections to be joined, and so satisfactory ultrasonic bonding cannot be performed.

In contrast, in a case of performing ultrasonic bonding as in the structure above by abutting the projection terminal 1C of the semiconductor element 1 and the through-via 2C of the film substrate 2 while transmitting ultrasonic waves to the projection terminal 1C and the through-via 2C with the ultrasonic bonding tool 15, it is possible to directly transmit ultrasonic waves to the metal projection terminal 1C from the metal through-via 2C, and so it is possible to perform ultrasonic bonding without attenuation of the vibrations.

Also, in the case of performing ultrasonic bonding on the mounting substrate 5 that is a rigid substrate and that can more favorably transmit vibrations than resin such as polyamide, if the film substrate 2 is stacked on the mounting substrate 5 as shown in FIG. 2 and ultrasonic bonding is performed under the aforesaid conditions while pressing the ultrasonic bonding tool 15 from above on the field-via 11 of the mounting substrate 5 for the region where the through-via 1C was disposed, the pressure from the ultrasonic bonding tool 15 and the ultrasonic vibrations can be sufficiently applied on the interface of the field-via 11 and the through-via 1C, and so favorable ultrasonic bonding can be performed. Also, for the regions where the through-via 2C of the film substrate 2 is disposed on the wiring 13 of the mounting substrate 5, it is possible to perform ultrasonic bonding under the aforementioned conditions by pressing the bonding tool 15 from above. Note that the mounting substrate 5, from the abovementioned viewpoints, is preferably a substrate with higher rigidity than the film-shaped substrate body 2A as a result of a filler and additive, etc. being mixed with a thermosetting resin, and is constituted so as to favorably transmit ultrasonic vibrations.

Next, since a coating having Au as the main component is formed at the portion at which the projection terminal 1C of the semiconductor element 1 is ultrasonically bonded, that is, on the upper face side of the through-via 2C of the film substrate 2, and a coating layer having Au as the main component is formed on the upper face side of the through-via 2C of the film substrate 2 of the side at which the projection terminal 1C is joined, the interface that is ultrasonically bonded undergoes bonding by Au and Au, and so electrical conduction and mechanical bonding force are obtained with sufficient bonding strength and conductivity due to the ultrasonic bonding. Note that the Ni layer that serves as the foundation of the coating layer having Au as the main body is applied in the case of the metal that constitutes the projection terminal 1C or the metal that constitutes the through-via 2C leading to a problem in the mechanical bonding power with the Au, however, it may be omitted in the case of the projection terminal 1C and the through-via 2C consisting of a material having a high bonding power with Au.

Also, similarly to the portion where the through-via 2C of the film substrate 2 is ultrasonically bonded to the wiring 13 of the mounting substrate 5 or the portion where the through-via 2C is ultrasonically bonded on the field-via 11 of the mounting substrate 5, since a covering layer 18 which has Au as a main component is formed on the wiring 13 of the mounting substrate 5, and the covering layer 18 which has Au as a main component is formed on the field-via 11, the interface that is ultrasonically bonded undergoes bonding by Au and Au, and so electrical conduction and mechanical bonding force are obtained with sufficient bonding strength and conductivity due to the ultrasonic bonding.

The semiconductor device B in which the film substrate 2 provided with the semiconductor element 1 is joined on the mounting substrate 5 is provided for practical use by additionally attaching to an aggregate board 20 such as a large motherboard as shown for example in FIG. 3. Here, in the case of joining the field-via 11 on the rear face side of the mounting substrate 5 or the wiring 14 on the rear face side to the aggregate board, it is possible to apply conventional methods in joining of substrates, such as the joining method by soldering or ball bonding. Also, front face side wiring or internal wiring and the like is formed on the aggregate board 20, with a monolayer substrate or multilayer substrate or the like being used, with details omitted in FIG. 2.

In the structure of the embodiment explained above, by using the film substrate 2 in which formation of circuits such as wiring is possible on the front and rear, wiring that is suitable for high speed signal transmission (for example, microstrip configuration) is formed, and by ultrasonically joining various lines with the projection terminals 1C formed on the semiconductor element 1, electrical connections with low parasitic inductance are achieved. Also, a bonding state with high mechanical strength is obtained at the bonded portions where ultrasonic connection is performed.

Moreover, by providing through-vias 2C that enable electrical connection of the front and rear of the film substrate 2, ultrasonic vibration is easily transmitted, and for that reason joining with the mounting substrate 5, which is the next mounting stage, can be achieved at a temperature that is lower than the solder melting temperature. By utilizing this ultrasonic joining means, it is possible to form stacked structures comparatively easily without temperature hierarchy, even if it is multi-stage stacked structure.

Also, when attaching the semiconductor element unit A to the mounting substrate 5, it is possible to perform inspection of the semiconductor element 1 using the wiring 2D that is formed on the film substrate 2, and if only the semiconductor element unit A that passes this inspection is attached to the mounting substrate 5, it is possible to prevent the attachment of defective articles. Note that in the wiring 13 of the semiconductor element unit A, it becomes not a single component of the semiconductor element 1, but a wiring expanded staged structure, and so it is possible to perform precise tests including speed operation tests. On this point, if a single component of the semiconductor element 1, it is possible to some perform tests with a tester or a probe of a survey instrument, but high speed tests of the high speed signal input and the like are difficult, but if high speed test in the state of the semiconductor element unit A, it is possible to perform testing in a state that is closer to the actual usage state, and so it is possible to select a perfectly conforming article.

FIG. 4 and FIG. 5 are lineblock diagrams that show the first embodiment according to a semiconductor element unit complex of the present invention. The semiconductor element unit complex F of this first embodiment is a two-storied structure of the semiconductor element unit A of the embodiment described previously.

The semiconductor element unit A that is applied to this embodiment, similarly to the previous embodiment, has a structure of the semiconductor element 1 being attached to the film substrate 2, with the constitution of the film substrate 2 having a through-via 2C formed in the substrate body 2A, and the constitution of the through-via 2C having a flange portion 2F and having a bonding layer 9 that consists of a foundation layer 7 and a covering layer 8 being equivalent.

The characteristic point of the semiconductor element unit complex F of this embodiment is, along with two of the semiconductor element units A being stacked, the film-shaped substrate body 2A of the upper stage side semiconductor element unit A is placed on the semiconductor element 1 of the lower stage side semiconductor element unit A, both ends of the substrate body 2A being flexed to the lower stage side semiconductor element unit A, both end portions of the substrate body 2A being aligned on the substrate body 2A of the lower stage side semiconductor element unit A, and the upper and lower semiconductor element units A, A being joined by performing ultrasonic bonding of the required portions of the through-vias 2C of the upper stage side substrate body 2A to the required portions of the through-vias 2C of the lower stage side substrate body 2A.

Also, in the semiconductor element unit complex F of the present embodiment, the through-vias 2C that are disposed at the end portion side in the film shaped substrate body 2A of the upper stage side semiconductor element unit A are stacked on the through-vias 2C that are disposed at the end portion side in the film shaped substrate body 2A of the lower stage side semiconductor element unit A, and both semiconductor element units A, A are bonded and integrated by ultrasonically bonding the required through-vias 2C among those that are vertically stacked.

It is acceptable to perform ultrasonic bonding under the aforesaid welding conditions using the ultrasonic bonding tool 15 that was used in the previous embodiment.

According to the structure of this embodiment, it is possible to perform electrical and mechanical bonding at a temperature that is close to room temperature, which is below the temperature of soldering the top and bottom semiconductor element units A, A, and so cubic integration of the semiconductor element unit A can be readily done. Also, by electrically and mechanically bonding at a temperature that is close to room temperature, which is below the soldering temperature, it is possible to integrate without adding thermal stress to the semiconductor elements 1, 1 that are mounted on the semiconductor element unit A, and so it is possible to obtain a high bonding strength by ultrasonic bonding of the through-vias 2C.

FIG. 5 shows an example structure of a semiconductor device 25 in which the aforesaid semiconductor element unit complex F is connected to the mounting substrate 5 that was applied in the previous embodiment.

The mounting substrate 5 shown in FIG. 5, similarly to the mounting substrate 5 of the embodiment described previously, has a structure referred to as a multilayer wiring printed circuit board, and so is configured by joining and integrating internal printed circuit boards of a plurality of layers. Field-vias 11 of a type that pass through the internal printed circuit boards at each layer and internal wiring 12 that is provided on the front face portion side and rear face portion side of the internal printed circuit boards are provided. On the front face side of the mounting substrate 5, among the field-vias 11 that pass through the internal printed circuit boards, front face side wiring 13 and top face side terminals 13a that are connected to those field-vias 11 that reach the top face of the mounting substrate 5 are provided. On the rear face side of the mounting substrate 5, among the field-vias 11 that pass through the internal printed circuit boards, rear face side wiring 14 and rear face side terminals 14a that are connected to those field-vias 11 that reach the rear face of the mounting substrate 5 are provided. Also, a bonding layer 19 that consists of a foundation layer 17 of Ni plate and a covering layer 18 having Au as the main component is formed on the front face side wiring 13 and top face side terminals 13a of the mounting substrate 5.

In the present embodiment, among the through-vias 2C that are formed in the substrate body 2A of the lowest stage semiconductor element unit A in the semiconductor element unit complex F, the required ones are ultrasonically bonded to the front face side wiring 13 that is disposed on the top face side of the mounting substrate 5, and so bonded and integrated to the mounting substrate 5.

The mounting substrate 5 in this structure is a rigid substrate with a high degree of hardness. By arranging the through-vias 2C of the semiconductor element unit A side on the front face side wiring 13 of the mounting substrate 5 and impressing ultrasonic vibrations while applying pressure from the top with the ultrasonic bonding tool 15, it is possible to bond them.

In this case, as shown in FIG. 5, there are the through-vias 2C of the upper stage side semiconductor element unit A, the through-vias 2C of the lower stage side semiconductor element unit A and the wiring 13 of the front face side of the mounting substrate 5, and moreover the portion where the field-vias 11 are formed thereunder, resulting in a structure of the three vias 2C, 2C and 11 being stacked. After the three are stacked, it is possible to perform bonding by impressing ultrasonic vibrations while applying pressure with the ultrasonic bonding tool 15 once.

Also, in the case of performing three-stage ultrasonic bonding, ultrasonic bonding may be performed in the order of ultrasonic bonding with the through-vias 2C of the lower stage side semiconductor element unit A stacked on the field-vias 11 of the mounting substrate 5, followed by ultrasonic bonding with the through-vias 2C of the upper stage side semiconductor element unit A stacked thereon.

The semiconductor device 25 that is constituted as described above of course may further be attached to the aggregate board 20 having a structure shown in FIG. 2.

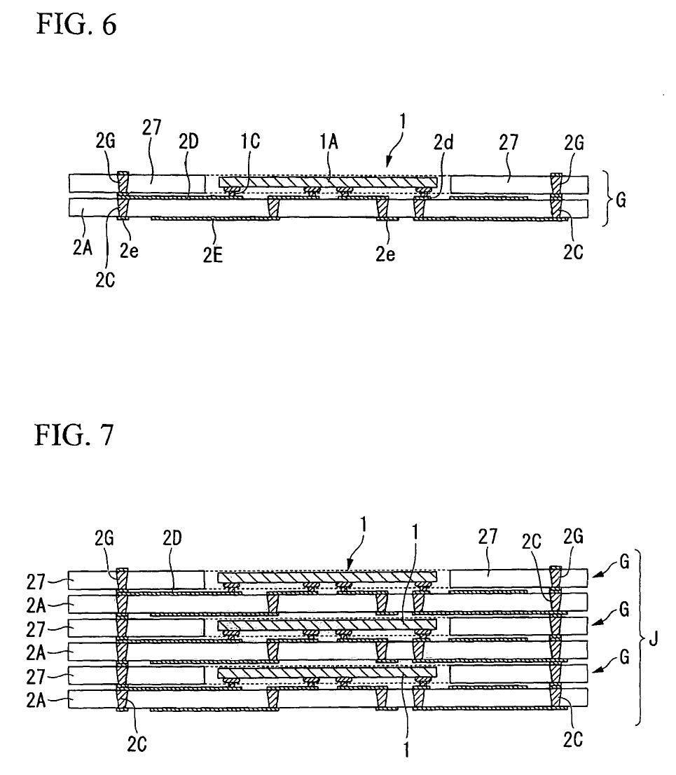

FIG. 6 is a lineblock drawing that shows another embodiment according to the semiconductor element unit complex of the present invention. A semiconductor element unit complex G of this embodiment is one that is constituted by providing spacer substrates 27 in the semiconductor element unit A of the embodiment described previously.

In the semiconductor element unit complex G of this embodiment, the spacer substrates 27 of a thickness equal to the semiconductor element 1 or greater are disposed on the film shaped substrate body 2A of the semiconductor element unit A so as to be positioned around the semiconductor element, and through-vias 2G in which a conductive material is filled in through-holes that are provided in the front and rear of the spacer substrates 27 are formed, and the through-vias 2G that are formed in the spacer substrates 27 are installed on the through-vias 2C that are provided on the film shaped substrate body 2A, and the spacer substrates are bonded to the substrate body by ultrasonically bonding both of the through-vias 2G; 2C.

Each of the through-vias 2G of this structure has the same structure as the though vias 2C described in the preceding embodiment.

The semiconductor element unit complex G of this embodiment has the characteristic of having a flat top surface, with the top surface of the semiconductor element 1 and the top surface of the spacer substrates 27 being approximately flush.

As a result, even in the case of stacking a plurality of this semiconductor element unit complexes G having this flat top face structure, a structure that can be vertically stacked with no unevenness is achieved. FIG. 7 shows an example of this stacked structure.

FIG. 7 shows the structure example of a plurality of the semiconductor element unit complexes G with the aforesaid structure being stacked. Therefore, the stacked structure of a plurality of semiconductor element unit complexes G shall be referred to as a semiconductor device module in the present specification.

A semiconductor device module J of this embodiment has structure consisting of three of the semiconductor element unit complexes G being stacked, and in this embodiment, the through-vias 2G, 2C of each semiconductor element unit complex G that is stacked vertically are all arranged in a vertical row, and so the through-vias 2C, 2G that make vertical contact are ultrasonically bonded to each other.

The semiconductor element unit complex G that is provided with the spacer substrates 27 as in this embodiment can be stacked to a required number. In that case, all of the film-shaped base plate bodies 2A can be bonded in a parallel and well-settled manner.

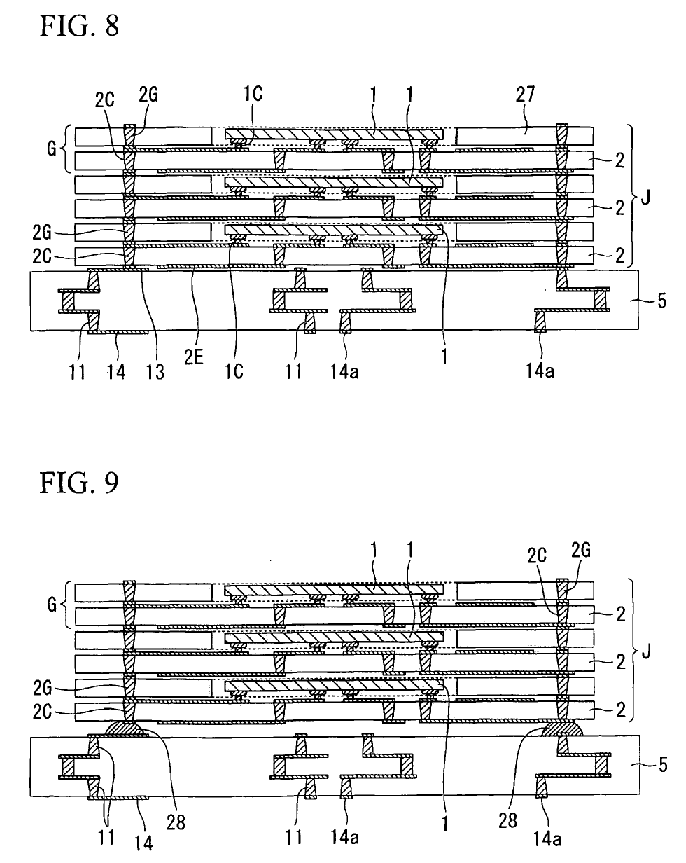

FIG. 8 shows an assembled structure of the semiconductor device module J in which the semiconductor device module J described in the preceding embodiment is bonded to the mounting substrate 5.

Even in the assembled structure of the semiconductor device module J of this embodiment, similarly to the structure of the semiconductor structure B shown in FIG. 1, the through-vias 2C of the lowest-stage film substrate 2 are ultrasonically bonded to the wiring 13 or terminals 13a of the front face side of the mounting substrate 5 to be bonded and integrated to the mounting substrate 5.

Even in the structure of this embodiment, similarly to the case of the preceding embodiment, for the portions that position the through-vias 2C of the film substrate 2 on the field-vias 11 positioned on the top face portion of the mounting substrate 5, by pressing the ultrasonic bonding tool 15 from above, it is possible to perform ultrasonic bonding under the conditions given above. Also, for the portions that position the through-vias 2C of the film substrate 2 on the front face side wiring 13 positioned on the top face portion of the mounting substrate 5, by pressing the ultrasonic bonding tool 15 from above, it is possible to perform ultrasonic bonding under the conditions given above.

To assemble the semiconductor device module J on the mounting substrate 5 in the structure of FIG. 8, one integrated as the semiconductor device module J once shown in FIG. 7 by ultrasonic bonding, after being stacked on the mounting substrate 5, may be bonded once using the ultrasonic bonding tool 15 shown in FIG. 2, and after ultrasonically bonding one semiconductor element unit complex G on the mounting substrate 5, the semiconductor element unit complexes G may one by one be ultrasonically bonded in the necessary number order so as to ultrasonically bond the semiconductor element unit complex G of the second layer and next ultrasonically bond the semiconductor element unit complex G of the third layer.

FIG. 9 shows another example of the assembled structure of the semiconductor device module J in which the semiconductor device module J described in the preceding embodiment is bonded to the mounting substrate 5.

This example shows an embodiment in which, after obtaining the semiconductor device module J shown in FIG. 7, the semiconductor device module J is assembled via joining portions with soldering to the wiring 13 or terminals 13a of the mounting substrate 5. If the foundation layer 7 and the covering layer 8 having Au as the main component described previously are layered on the wiring 13 or the terminal 13, it is possible to readily join to the mounting substrate 5 by soldering instead of ultrasonic bonding.

It is acceptable to employ a means other than ultrasonic bonding in the case of bonding to the mounting substrate 5 as described above.

Even in the assembled structure of the semiconductor device module J shown in either FIG. 8 or FIG. 9, high integration of the semiconductor element 1 is possible. Moreover, even when each film-shaped substrate body 2A has flexibility with little rigidity, if a semiconductor device module J in which a plurality are ultrasonically bonded to each other, in the case of operator or robot handling, it has suitable rigidity, and so in the case of manufacturing an assembled structure of the semiconductor device module J shown in FIG. 8 and FIG. 9, workability improves, and manufacture becomes easy.

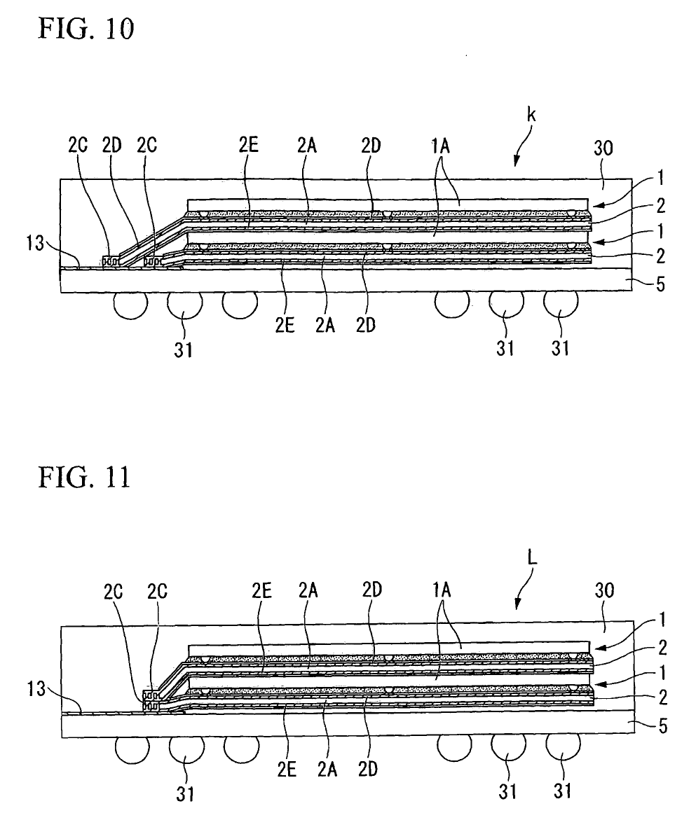

FIG. 10 is a conceptual diagram that shows the state of a second embodiment of the semiconductor complex device unit of the present invention as a package product type.

A semiconductor element unit complex K of this second embodiment is a two-storied structure of the semiconductor element unit A of the first embodiment described previously.

The semiconductor element unit A that is applied to this embodiment, similarly to the previous embodiment, has a structure of the semiconductor element 1 being attached to the film substrate 2, with the constitution of the film substrate 2 having through-vias 2C formed in the substrate body 2A, and the constitution of the through-vias 2C being equivalent.

The characteristic point of the semiconductor element unit complex K of this embodiment is, along with two of the semiconductor element units A being stacked on the mounting substrate 5, the film-shaped substrate body 2A of the upper stage side semiconductor element unit A is placed on the semiconductor element 1 of the lower stage side semiconductor element unit A, one end side of the substrate body 2A (the left end portion side in FIG. 10) being flexed to the lower stage side semiconductor element unit A, one end portion side of the substrate body 2A extending past the substrate body 2A of the lower stage side semiconductor element unit A to be aligned on the mounting substrate 5, and the upper and lower semiconductor element units A, A being bonded to the mounting substrate 5 by performing ultrasonic bonding of the required ones of the through-vias 2C of the upper stage side substrate body 2A and the required ones of the through-vias 2C of the lower stage side substrate body 2A to shifted positions of the wiring 13 of the front face side of the mounting substrate 5.

Also, the semiconductor element units A, A on the mounting substrate 5 are covered by a sealing portion that consists of a sealing material, and a required number of solder balls 31 are formed as connection terminals on the bottom surface of the mounting substrate 5.

FIG. 11 is a conceptual diagram that shows the state of a third embodiment of the semiconductor complex element unit of the present invention as a package product type.

A semiconductor element unit complex L of this second embodiment is a two-storied structure of the semiconductor element unit A of the first embodiment described previously.

The semiconductor element unit A that is applied to this embodiment, similarly to the previous embodiment, has a structure of the semiconductor element 1 being attached to the film substrate 2, with the constitution of the film substrate 2 having through-vias 2C formed in the substrate body 2A, and the constitution of the through-vias 2C being equivalent.

The characteristic point of the semiconductor element unit complex L of this embodiment is, along with two of the semiconductor element units A being stacked on the mounting substrate 5, the film-shaped substrate body 2A of the upper stage side semiconductor element unit A is placed on the semiconductor element 1 of the lower stage side semiconductor element unit A, one end side of the substrate body 2A (the left end portion side in FIG. 10) being flexed to the lower stage side semiconductor element unit A, one end portion side of the substrate body 2A being stacked on one end side of the substrate body 2A of the lower stage side semiconductor element unit A to be aligned on the mounting substrate 5, and the upper and lower semiconductor element units A, A being joined to the mounting substrate 5 by performing ultrasonic bonding of the required ones of the through-vias 2C of the upper stage side substrate body 2A and the required ones of the through-vias 2C of the lower stage side substrate body 2A to the front face side wiring 13 of the mounting substrate 5.

Also, the semiconductor element units A, A on the mounting substrate 5 are covered by a sealing portion that consists of a sealing material, and a required number of solder balls 31 are formed as connection terminals on the bottom face side of the mounting substrate 5.

Since these semiconductor element unit complexes K, G, in FIG. 10 and FIG. 11 are provided with the semiconductor element unit A, since it is in a film shape in which wiring circuits are formed on the front and rear, it is possible to mount wiring suited to high-speed signal transmission such as for example a microstrip configuration, and by connecting the wiring with the projection terminals 1C on the semiconductor element 1 by ultrasonic bonding, electrical connections with low parasitic inductance are achieved, and so the same effect as the semiconductor complex device unit of the preceding first embodiment is obtained. Also, since any of the through-vias 2C of the semiconductor element unit A has a structure of being filled with a conductive metal material such as plated copper, and it is possible to transmit ultrasonic vibrations without vibration attenuation, bonding of the ultrasonic bonding portions is reliably performed. Of course, since the bonding that occurs in the ultrasonic bonding is possible at a temperature that is close to room temperature, the semiconductor elements 1, 1 are not thermally damaged during bonding.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A semiconductor element unit comprising:
a film substrate that is provided with through-vias including a conductive metal material filled in through-holes that pass through the front and rear of a film-shaped substrate body, and wiring or terminals connected to the through-vias; and
a semiconductor element attached to the film-shaped substrate body, and having terminal members electrically connected to the wiring or the terminals.

2. The semiconductor element unit according to claim 1, wherein the wiring or the terminals of the film-shaped substrate body and the terminal members of the semiconductor element are bonded.

3. The semiconductor element unit according to claim 2, wherein at least the front face of the terminal members of the semiconductor element and at least the front face of the wiring or the terminals of the film-shaped substrate body are formed with a covering layer that has Au as a main component.

4. A semiconductor device in which the film-shaped substrate body of the semiconductor element unit according to claim 1 is bonded to a multilayer wiring substrate by ultrasonically bonding the through-vias to wiring or terminals on the front face side of the multilayer wiring substrate.

5. A semiconductor device in which the film-shaped substrate body of the semiconductor element unit according to claim 1 is bonded to a multilayer wiring substrate by ultrasonically bonding the through-vias to wiring or terminals on vias on the front face side of the multilayer wiring substrate.

6. A semiconductor element unit complex comprising:
the semiconductor element units recited in claim 1 that are stacked on an upper stage and a lower stage, and a multilayer wiring substrate that electrically connects the upper-stage side and the lower-stage side semiconductor element units; wherein:
the film-shaped substrate body of the upper-stage side semiconductor element unit is disposed on the semiconductor element of the lower-stage side semiconductor element unit by being flexed toward the lower-stage side semiconductor element unit; and
the end portions of the film-shaped substrate body of the upper-stage side semiconductor element unit and the end portions of the film-shaped substrate body of the lower-stage side semiconductor element unit are aligned in the surface direction of the multilayer wiring substrate and ultrasonically bonded to wiring or terminals on the side of the multilayer wiring substrate.

7. A semiconductor element unit complex comprising:
the semiconductor element units recited in claim 1 that are stacked on an upper stage and a lower stage, and a multilayer wiring substrate that electrically connects the upper-stage side and the lower-stage side semiconductor element units; wherein:
the film-shaped substrate body of the upper-stage side semiconductor element unit is disposed on the lower-stage side semiconductor element unit by being flexed toward the lower-stage side semiconductor element unit; and
the end portion side of the substrate body of the upper-stage side semiconductor element unit is aligned on the substrate body of the lower-stage side semiconductor element unit, and through-vias of the substrate body of the upper-stage side semiconductor element unit are ultrasonically bonded to wiring or terminals on the side of the multilayer wiring substrate via through-vias of the substrate body of the lower-stage side semiconductor element unit.

8. A semiconductor device in which, in the semiconductor element unit complex recited in claim 6, the film-shaped substrate bodies of the semiconductor element units are bonded to the multilayer wiring substrate by ultrasonically bonding the through-vias to the wiring or terminals on the front face side of the multilayer wiring substrate.

9. A semiconductor device in which, in the semiconductor element unit complex recited in claim 7, the film-shaped substrate bodies of the semiconductor element units are bonded to the multilayer wiring substrate by ultrasonically bonding the through-vias to the wiring or terminals on vias of the front face side of the multilayer wiring substrate.

10. A semiconductor element unit complex comprising:
spacer substrates disposed on the film-shaped substrate body of the semiconductor element unit recited in claim 1 so as to be positioned around the semiconductor element and having a thickness equal to or greater than the semiconductor element;
through-vias formed by filling a conductive metal material in through-holes that are provided passing through the front and rear of the spacer substrates; and
through-vias provided in the film-shaped substrate body; wherein
the through-vias formed in the spacer substrates are installed on the through-vias provided in the film-shaped substrate body, and the spacer substrates are bonded to the substrate body by ultrasonically bonding both vias.

11. A semiconductor device module in which a plurality of the semiconductor device unit complexes recited in claim 10 are vertically stacked, and through-vias of an upper-stage side semiconductor element unit complex are installed on through vias of a lower-stage side semiconductor element unit complex, and the lower-stage side semiconductor element unit complex and the upper-stage side semiconductor element unit complex are bonded by ultrasonically bonding the vias thereof.

12. The semiconductor device module according to claim 11, in which through-vias that bond the film-shaped substrate bodies of the semiconductor device unit complexes vertically stacked are connected in a vertical line from the through-vias of the uppermost-stage semiconductor element unit complex to the through-vias of the lowermost-stage semiconductor element unit complex.

13. A semiconductor device module assembled structure in which the semiconductor device module recited in claim 11 is bonded to a multilayer wiring substrate by ultrasonically bonding the through-vias of the lowermost-stage semiconductor element unit complex to wiring or terminals on the multilayer wiring substrate.

14. The semiconductor device module assembled structure according to claim 13, in which wiring or terminals electrically connected by the through-vias are provided on the front face side and rear face side of the film-shaped substrate bodies, and the plurality of terminal members of the semiconductor devices of the plurality of semiconductor device modules vertically stacked are connected to the wiring or terminals of the multilayer wiring substrate via the wiring or terminals and through-vias of the film-shaped substrate bodies.

15. A film substrate connection structure comprising:
a film substrate provided with a film-shaped substrate body;
through-holes formed in the substrate body and passing through the substrate body in the thickness direction;
through-vias formed by filling a conductive material in the through-holes;
a bonding layer including a plurality of covering layers of a conductive material formed on at least one of the bonding faces of the through-vias positioned on the front face side or the rear face side of the substrate body;
a mounting substrate including a rigid substrate to which the film substrate is bonded; and
wiring or terminals formed on the mounting substrate; wherein
the film substrate is bonded to the mounting substrate by ultrasonically bonding the front face of the bonding layer of the through-vias to the front face of the wiring or terminals of the mounting substrate.

16. The film substrate connection structure according to claim 15, wherein the front face of the bonding layer including a covering bonding layer that has Au as a main component, and the front face of the wiring including a front face layer that has Au as a main component, and the film substrate causes the covering bonding layer to abut the front face layer so that the through-vias are bonded.

17. A film substrate connection structure comprising:
a film substrate provided with a film-shaped substrate body;
through-holes formed so as to pass through the substrate body in the thickness direction;
through-vias formed by filling a conductive material in the through-holes; and
a bonding layer formed on at least one of the bonding faces of the through-vias positioned on the front face side or the rear face side of the substrate body; wherein
the plurality of film substrates are stacked with the through-vias provided in each film substrate being stacked in the vertical direction at the same position in the surface direction of the film substrates, and the plurality of film substrates are bonded by bonding the through-vias vertically stacked with ultrasonic bonding.

18. The film substrate connection structure according to claim 17, wherein the front face layer of the bonding layer of the through-vias including a covering bonding layer that has Au as a main component, and the plurality of film substrates are bonded via the stacked through-vias by the covering bonding layer of the film substrate being ultrasonically bonded to the covering bonding layer of another film substrate.
